(19) United States
(12) Patent Application Publication
(10) Pub. No.: US 2012/0060904 A1
(43) Pub. Date: Mar. 15, 2012

(54) Fabrication Of Solar Cells With Silicon Nano-Particles

(76) Inventors: David D. SMITH, Campbell, CA (US); Taeseok KIM, San Jose, CA (US)

(21) Appl. No.: 12/940,821

(22) Filed: Nov. 5, 2010

Related U.S. Application Data
(60) Provisional application No. 61/382,384, filed on Sep. 13, 2010.

(51) Int. Cl. H01L 31/0264; H01L 31/18

(52) U.S. Cl. 136/252; 438/63; 257/E31.051; 977/773; 977/948

(57) ABSTRACT

A solar cell structure includes silicon nano-particle diffusion regions. The diffusion regions may be formed by printing silicon nano-particles over a thin dielectric, such as silicon dioxide. A wetting agent may be formed on the thin dielectric prior to printing of the nano-particles. The nano-particles may be printed by inkjet printing. The nano-particles may be thermally processed in a first phase by heating the nano-particles to thermally drive out organic materials from the nano-particles, and in a second phase by heating the nano-particles to form a continuous nano-particle film over the thin dielectric.

### CROSS-REFERENCE TO RELATED APPLICATION

This application claims the benefit of U.S. Provisional Application No. 61/382,384, filed on September 13, 2010, entitled “Fabrication of Solar Cells with Silicon Nano-Particles”.

### STATEMENT REGARDING FEDERALLY SPONSORED RESEARCH OR DEVELOPMENT

The invention described herein was made with Governmental support under contract number DE-FC36-07GO17043 awarded by the United States Department of Energy. The Government may have certain rights in the invention.

### TECHNICAL FIELD

The present invention relates generally to solar cells, and more particularly but not exclusively to solar cell fabrication processes and structures.

### BACKGROUND

A typical solar cell includes P-type and N-type diffusion regions. Solar radiation impinging on the solar cell creates electrons and holes that migrate to the diffusion regions, thereby creating voltage differentials between the diffusion regions. The diffusion regions may be formed within a solar cell substrate, or in a layer external to the solar cell substrate. For example, the diffusion regions may be formed by diffusing dopants into the substrate. In externally formed diffusion regions, a layer of material, such as polysilicon, is formed on the substrate. Dopants are thereafter diffused into the polysilicon to form the diffusion regions.

Embodiments of the present invention pertain to processes and structures that lower fabrication costs associated with formation of solar cell diffusion regions.

### BRIEF SUMMARY

In one embodiment, a solar cell structure includes silicon nano-particle diffusion regions. The diffusion regions may be formed by printing silicon nano-particles over a thin dielectric, such as silicon dioxide. A wetting agent may be formed on the thin dielectric prior to printing of the nano-particles. The nano-particles may be printed by inkjet printing. The nano-particles may be thermally processed in a first phase by heating the nano-particles to thermally drive out organic materials from the nano-particles, and in a second phase by heating the nano-particles to form a continuous nano-particle film over the thin dielectric.

These and other features of the present invention will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The drawings are not drawn to scale.

FIG. 1 shows a cross-section schematically illustrating a solar cell structure in accordance with an embodiment of the present invention.

FIG. 2 shows a flow diagram of a method of fabricating a solar cell structure in accordance with an embodiment of the present invention.

FIG. 3 shows plots relating nano-particle radius to melting point.

### DETAILED DESCRIPTION

In the present disclosure, numerous specific details are provided, such as examples of apparatus, materials, process steps, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

The present disclosure pertains to the use of silicon nano-particles in solar cells. The use of silicon nano-particles in solar cells is also disclosed in commonly-owned U.S. Pat. No. 7,705,237, which is incorporated herein by reference in its entirety.

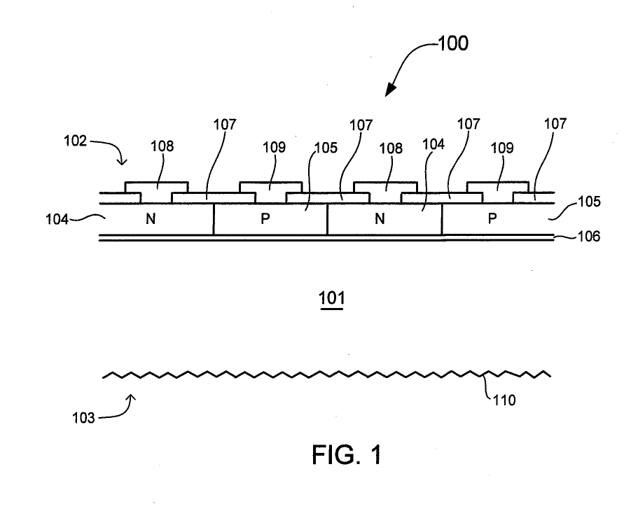

FIG. 1 shows a cross-section schematically illustrating a solar cell structure 100 in accordance with an embodiment of the present invention. The solar cell structure 100 includes a backside 102 and a front side 103. The front side 103 faces the sun to collect solar radiation during normal operation. The backside 102 is opposite the front side 103. The solar cell structure 100 is a backside contact solar cell in that the N-type diffusion regions 104, the P-type diffusion regions 105, as well as their respective metal contacts 108 and 109 are on the backside 102.

The solar cell structure 100 includes a solar cell substrate in the form of a silicon substrate 101, which in the example of FIG. 1 comprises an N-type monocrystalline silicon wafer. The front side surface of the silicon substrate 101 is textured, e.g., with random pyramids 110, for improved solar radiation collection efficiency.

A thin dielectric in the form of silicon dioxide 106 is on the backside surface of the silicon substrate 101. In one embodiment, the silicon dioxide 106 is thermally grown on the backside surface of the silicon substrate 101. Amorphous silicon (not specifically shown) may thereafter be formed on the surface of the oxide 106. The amorphous silicon serves as a wetting agent for facilitating formation of the N-type diffusion regions 104 and P-type diffusion regions 105. The N-type diffusion regions 104 and P-type diffusion regions 105 are formed over the oxide 106, either directly on the oxide 106 or on the wetting agent if one is present.

In one embodiment, the N-type diffusion regions 104 and P-type diffusion regions 105 comprise silicon nano-particles. The silicon nano-particles may be commercially obtained from material vendors, including Innovalight, Inc. of Sunnyvale, Calif. The N-type diffusion regions 104 and the P-type diffusion regions 105 are alternately formed over the oxide 106. An interlevel dielectric layer 107 provides electrical insulation over the N-type diffusion regions 104 and P-type diffusion regions 105. Metal contacts 108 are electrically coupled to corresponding N-type diffusion regions 104 by way of contact holes through the dielectric layer 107. Similarly, metal contacts 109 are electrically coupled to corresponding P-type diffusion regions 105 by way of contact holes through the dielectric layer 107. The metal contacts 108 and 109, which may comprise aluminum, copper, or other metallization material, may be interdigitated. The metal contacts 108 and 109 allow an external electrical circuit to be coupled to and be powered by the solar cell.

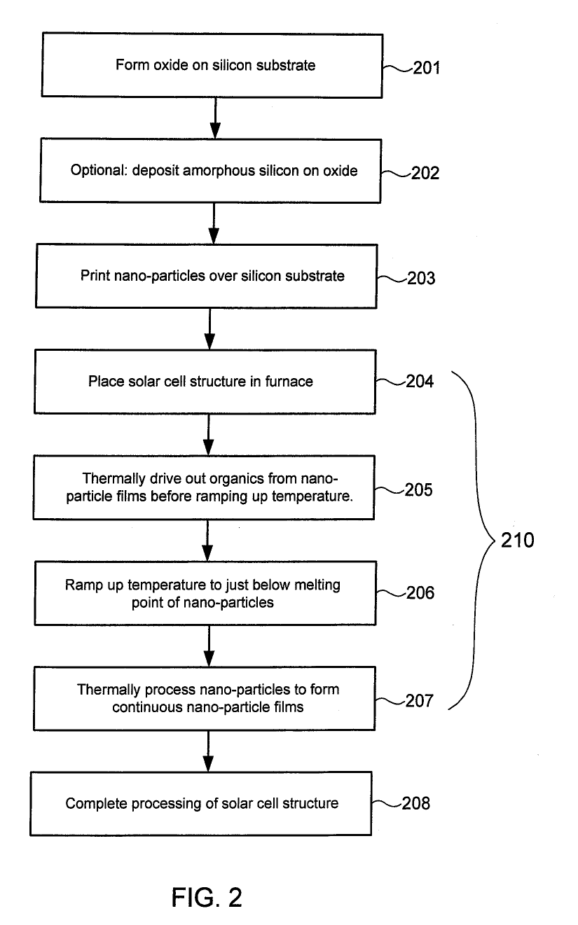

FIG. 2 shows a flow diagram of a method of fabricating the solar cell structure 100 in accordance with an embodiment of the present invention. In the example of FIG. 2, the method may begin by forming silicon dioxide 106 on the backside surface of the silicon substrate 101 (step 201). The oxide 106 serves as a thin dielectric layer between the silicon substrate 101 and the N-type and P-type diffusion regions. The oxide 106 may be thermally grown on the backside surface of the silicon substrate 101 to a thickness of about 7 to 20 Angstroms, such as about 10 Angstroms, for example.

Optionally, a layer of amorphous silicon may be deposited on the oxide 106 (step 202). The amorphous silicon serves as a wetting agent for facilitating printing of the N-type diffusion regions 104 and P-type diffusion regions 105. A wetting agent may or may not be needed depending on the composition of the diffusion regions and their formation process.

The N-type diffusion regions 104 and the P-type diffusion regions 105 may be formed by printing nano-particles over the oxide 106 (step 203). Nano-particles may be pre-doped to have N-type conductivity or P-type conductivity prior to printing. This advantageously saves one or more process steps as there is no need to separately dope the nano-particles after formation over the oxide 106. More specifically, a step of depositing a dopant source on a layer of polysilicon and a thermal step to diffuse dopants from the dopant source into the layer of polysilicon to form external diffusion regions, as in other processes, are eliminated.

The N-type diffusion regions 104 and the P-type diffusion regions 105 may be printed directly on a surface of the oxide 106 when a wetting agent is not employed. Otherwise, the N-type diffusion regions 104 and the P-type diffusion regions may be printed on the wetting agent or another layer of material on the oxide 106. Preferably, the following thermal processing temperatures for the nano-particles are lower than the threshold of oxide dissociation. Suitable printing processes include inkjet printing and screen printing. Inkjet printing is preferred because it advantageously allows for printing of N-type diffusion regions 104 and P-type diffusion regions 105 in one pass of an inkjet printer head, i.e., in the same inkjet printing step.

A film of nano-particles comprising dopants of N-type conductivity (e.g., phosphorus) may be printed over the oxide 106 to serve as an N-type diffusion region 104. Similarly, a film of nano-particles comprising dopants of P-type conductivity (e.g., boron) may be printed over the oxide 106 to serve as a P-type diffusion region 105. The nano-particles may be also be formed by spin coating or other suitable process. The nano-particles may be pre-doped with dopants of appropriate conductivity type prior to formation over the oxide 106.

The particle size of the nano-particles may be selected for a particular melting point. The larger the particle size, the closer the melting point to the bulk value. In one embodiment, the nano-particles have a particle size of less than 10 nanometers, e.g., 7 nanometers. The nano-particles may also have a mixture of different particle sizes to facilitate formation of a continuous nano-particle film.

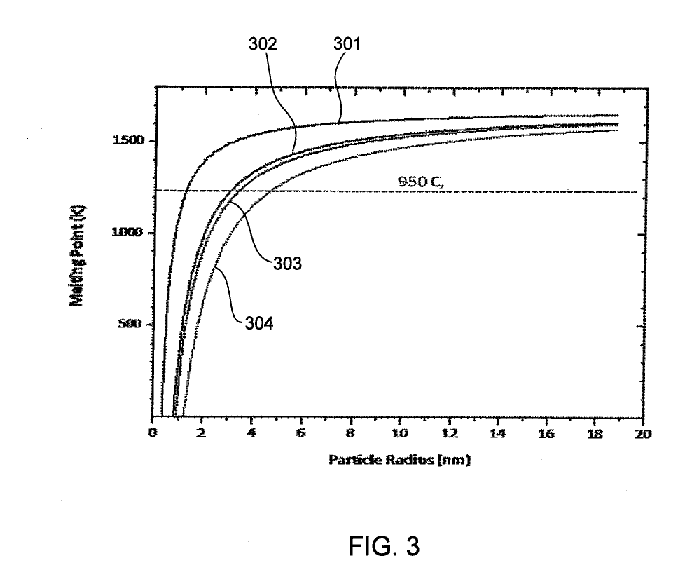

FIG. 3 shows plots relating nano-particle radius to melting point. FIG. 3 shows the reduction of melting temperature for a nano-particle, where the upper limit (plot 301) and the lower limit (plot 304) of the melting temperature are estimated by Couchman and Jesser (P. R. Couchman and W. A. Jesser, Nature 269, 481 (1977), and the median values are calculated by Buffat (plot 302; Ph. Buffat and J.-P. Borel, Phys. Rev. A 13, 2287 (1976)) and Wautelet (plot 303; M Wautelet, J. Phys. D 24, 343 (1991)). From these calculations, the inventors expect significant melting temperature reduction for nano-particle size lower than 10 nm diameter (best case), even when nano-particle size smaller than 4 nm diameter has been known to be too reactive to be used as a stable printing material in ambient temperature.

It is to be noted that FIG. 3 shows theoretical melting point depression for silicon nano-particles as a function of radius based on models from several groups. Experimental data, however, shows an even lower temperature melting point.

Continuing with FIG. 2, the nano-particles are thermally processed after printing over the oxide 106 (step 210). In the example of FIG. 2, the thermal processing includes steps 204-207, and involves placing the solar cell structure in a furnace (step 204) to be heated.

Thermal processing of the solar cell structure may be performed in two phases. In a first thermal processing phase, organic materials (e.g., isopropyl alcohol and functional groups coated on nano-particles) that may be in the nano-particle films are thermally driven out of the nano-particle films (step 205). This may be performed by moving the solar cell structure at a predetermined movement rate in the furnace at a predetermined intermediate temperature below 300° C. The first thermal processing phase is performed before ramping up the temperature of the furnace to a sintering temperature above the intermediate temperature.

In a second thermal processing phase, the temperature of the furnace is ramped up to the sintering temperature, which is a temperature just below the melting point of the nano-particles (step 206). For example, the temperature of the furnace may be ramped up to about 70% to 90% of the melting point of the nano-particles. Preferably, the sintering temperature is lower than the threshold of oxide dissociation.

In one embodiment where the melting point of the nano-particles is about 1000° C., the temperature of the furnace is ramped up to a sintering temperature of about 900° C. The solar cell structure is heated at the sintering temperature for a predetermined amount of time to achieve a continuous nano-particle film, especially at the interface with the oxide 106. For example, the solar cell structure may be heated to a temperature of about 900° C. for about 30 minutes. The resulting continuous nano-particle film advantageously allows the nano-particle film to behave the same way polysilicon does in other external diffusion solar cells, without the extra processing steps associated with polysilicon.

It is to be noted that a wetting agent (see step 202) may provide better wetting with molten nano-particles, which leads doping to the wetting region from the doped nano-particles, resulting in continuous diffusion layer on the substrate.

Additional processing steps are thereafter performed to complete the fabrication of the solar cell structure. These additional processing steps include formation of the dielectric layer 107, metal contacts 108 and 109, and other features of the solar cell.

Techniques for fabricating solar cells with silicon nano-particles have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method of fabricating a solar cell structure, the method comprising:
forming a thin dielectric layer on a solar cell substrate;
forming first diffusion regions of the solar cell structure by printing P-type doped silicon nano-particles over the thin dielectric layer;
forming second diffusion regions of the solar cell structure by printing N-type doped silicon nano-particles over the thin dielectric layer; and
forming a continuous nano-particle film over the thin dielectric layer by heating the N-type and P-type doped silicon nano-particles at a first temperature less than a melting point of the N-type and P-type doped silicon nano-particles.

2. The method of claim 1 further comprising:
prior to heating the N-type and P-type doped silicon nano-particles at the first temperature, removing organic materials from the N-type and P-type doped silicon nano-particles by heating the N-type and P-type doped silicon nano-particles at a second temperature less than the first temperature.

3. The method of claim 2 wherein the N-type and P-type doped silicon nano-particles are heated at the second temperature while being moved at a predetermined rate in a furnace.

4. The method of claim 1 wherein the N-type and P-type doped silicon nano-particles are printed by inkjet printing.

5. The method of claim 1 wherein the N-type and P-type doped silicon nano-particles are printed by inkjet printing in a same pass of an inkjet printing head.

6. The method of claim 1 wherein the solar cell substrate comprises a monocrystalline silicon substrate.

7. The method of claim 6 wherein the thin dielectric layer comprises silicon dioxide thermally grown on a surface of the silicon substrate.

8. The method of claim 1 further comprising:
forming a wetting agent on the thin dielectric prior to printing the N-type and P-type doped silicon nano-particles.

9. The method of claim 8 wherein the wetting agent comprises amorphous silicon.

10. The method of claim 1 wherein the N-type and P-type doped silicon nano-particles have a particle size less than 10 nanometers.

11. A solar cell structure fabricated by the method of claim 1.

12. A method of fabricating a solar cell structure, the method comprising:
growing silicon dioxide on a surface of a silicon substrate;
forming a diffusion region of the solar cell structure by printing silicon nano-particles over the silicon dioxide;
removing organic materials from the nano-particles by heating the nano-particles at a first temperature; and
forming a continuous nano-particle film over the silicon dioxide by heating the nano-particles at a second temperature higher than the first temperature, the second temperature being less than a melting point of the nano-particles.

13. The method of claim 12 wherein the silicon nano-particles are printed by inkjet printing in a same pass of an inkjet printing head.

14. The method of claim 12 further comprising:
forming a wetting agent on the silicon dioxide prior to printing the nano-particles.

15. The method of claim 14 wherein the wetting agent comprises amorphous silicon.

16. The method of claim 12 wherein the silicon nano-particles have a particle size less than 10 nanometers.

17. A solar cell structure fabricated by the method of claim 12.

18. A method of fabricating a solar cell structure, the method comprising:
forming a thin dielectric on a solar cell substrate;
forming a diffusion region of the solar cell structure by forming silicon nano-particles over the thin dielectric; and
heating the silicon nano-particles at a temperature below a melting point of the nano-particles.

19. The method of claim 18 further comprising:
forming a wetting agent between the thin dielectric and the diffusion region.

20. A solar cell structure fabricated by the method of claim 18.
